(19) United States
(12) Patent Application Publication
(10) Pub. No.: US 2026/0153799 A1
(43) Pub. Date: Jun. 4, 2026

(54) METHOD OF FORMING PATTERNS

(71) Applicant: SAMSUNG SDI CO., LTD., Yongin-si (KR)

(72) Inventors: Seol Hee LIM, Suwon-si (KR); Miyeon HAN, Suwon-si (KR); Jaeyeol BAEK, Suwon-si (KR); Jung Min CHOI, Suwon-si (KR); Seunghwan BYUN, Suwon-si (KR); Jonghyuk JEON, Suwon-si (KR); Sanghoon SHIN, Suwon-si (KR); Hyejin JANG, Suwon-si (KR)

(21) Appl. No.: 19/400,773

(22) Filed: Nov. 25, 2025

(30) Foreign Application Priority Data
Dec. 3, 2024 (KR) 10-2024-0177853

(51) Int. Cl. G03F 7/004; C07F 7/22; G03F 7/00; G03F 7/36

(52) U.S. Cl. CPC G03F 7/0042; C07F 7/226; C07F 7/2284; G03F 7/36; G03F 7/70033; H10P 50/71; H10P 50/73

(57) ABSTRACT

A method of forming or providing patterns is disclosed. The method of forming or providing patterns may include: forming or providing an etching target film on a substrate; coating a semiconductor photoresist composition including an organometallic compound and a solvent on the etching target film to form or provide a photoresist film; exposing the photoresist film utilizing a patterned mask; dry developing the photoresist film utilizing gas to form or provide a photoresist pattern; and etching the etching target film utilizing the photoresist pattern as an etching mask.

### CROSS-REFERENCE TO RELATED APPLICATION

The present application claims priority to and the benefit of Korean Patent Application No. 10-2024-0177853, filed on Dec. 3, 2024, in the Korean Intellectual Property Office, the entire content of which is incorporated herein by reference.

### BACKGROUND

### 1. Field

One or more embodiments of the present disclosure relate to a method of forming or providing patterns.

### 2. Description of the Related Art

Extreme ultraviolet (EUV) lithography is paid attention to as one essential technology to manufacture a next generation semiconductor device. The EUV lithography is a pattern-forming technology using an EUV ray having a wavelength of 13.5 nm as an exposure light source. According to the EUV lithography, an extremely fine pattern (e.g., less than or equal to 20 nm) may be formed or provided in an exposure process during a manufacture of a semiconductor device.

The extreme ultraviolet (EUV) lithography is realized through development of compatible photoresists which can be performed at a spatial resolution of less than or equal to 16 nm. Efforts to satisfy insufficient or unsuitable specifications of chemically amplified (CA) photoresists that are generally available, such as a resolution, a photospeed, and feature roughness (or also referred to as a line edge roughness or LER), for the next generation device are being made.

An intrinsic image blurring due to an acid catalyzed reaction in the polymer-type or kind photoresists limits a resolution in small feature sizes, which has been experienced in electron beam (e-beam) lithography for a long time. The chemically amplified (CA) photoresists are designed for high sensitivity, but because their elemental makeups reduce light absorbance of the photoresists at a wavelength of 13.5 nm and thus decrease their sensitivity, the chemically amplified (CA) photoresists may partially have more difficulties under an EUV exposure.

Also, the CA photoresists may have difficulties in the small feature sizes due to roughness issues, and line edge roughness (LER) of the CA photoresists experimentally turns out to be increased, as a photospeed is decreased partially due to an essence of acid catalyst processes. Accordingly, a novel high-performance photoresist is required or desired in a semiconductor industry because of these defects and problems of the CA photoresists.

In order to overcome the drawbacks of the chemically amplified (CA) organic photosensitive composition, an inorganic photosensitive composition has been researched. The inorganic photosensitive composition is mainly or predominantly utilized for negative tone patterning having resistance against removal by a developer composition due to chemical modification through nonchemical amplification mechanism. The inorganic composition contains an inorganic element having a higher EUV absorption rate than hydrocarbon and thus may secure sensitivity through the nonchemical amplification mechanism and, in addition, is less sensitive about a stochastic effect and thus may have low line edge roughness and the small number of defects.

Inorganic photoresists based on peroxopolyacids of tungsten mixed with tungsten, niobium, titanium, and/or tantalum are radiation-sensitive materials for patterning. These materials are effective or suitable to pattern large pitches for bilayer configuration or arrangement as far ultraviolet (deep UV), X-ray, and electron beam sources.

Utilizing cationic hafnium metal oxide sulfate (HfSOx) materials along with a peroxo complexing agent to image a 15 nm half-pitch (HP) through projection EUV exposure exhibits the highest performance of a non-CA photoresist and has a practicable photospeed near to a requirement for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient or unsuitable shelf-life stability. Second, a structural change of the materials for performance improvement or enhancement as a composite mixture is challenging. Third, development should be performed in a tetramethylammonium hydroxide (TMAH) solution at an extremely high concentration of 25 wt % and/or the like.

Molecules including tin (Sn) have excellent or suitable absorption of extreme ultraviolet rays. As for an organotin polymer among them, alkyl ligands are dissociated by light absorption and/or secondary electrons produced thereby and are crosslinked with adjacent chains through oxo bonds and thus enable the negative tone patterning which may not be removed by an organic developer. This organotin polymer exhibits greatly or substantially improved or enhanced sensitivity as well as maintains a resolution and line edge roughness, but the patterning characteristics should be additionally improved or enhanced for commercial availability.

### SUMMARY

One or more aspects of embodiments of the present disclosure are directed toward a method of forming or providing patterns which improves or enhances exposure characteristics and surface roughness and does not cause wiggling or pattern collapse due to pattern miniaturization.

Additional aspects of embodiments will be set forth in part in the description which follows and, in part, will be apparent from the description or may be learned by practice of the presented embodiments of the disclosure.

One or more embodiments of the present disclosure provide a method of forming or providing patterns which includes: forming or providing an etching target film on a substrate; coating a semiconductor photoresist composition including an organometallic compound and a solvent on the etching target film to form or provide a photoresist film; exposing the photoresist film utilizing a patterned mask; dry developing the photoresist film utilizing gas to form or provide a photoresist pattern; and etching the etching target film utilizing the photoresist pattern as an etching mask.

The method of forming or providing patterns according to one or more embodiments may implement a fine pattern having excellent or suitable resolution and reduced bridge defects through dry development.

### BRIEF DESCRIPTION OF THE DRAWINGS

The above and other aspects and features of certain embodiments of the present disclosure will become more apparent from the following description taken in conjunction with the accompanying drawings.

FIGS. 1A-1E are cross-sectional views illustrating the process sequence to describe a method of forming or providing patterns.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout, and duplicative descriptions thereof may not be provided in the specification.

In order to clearly illustrate the present disclosure, the description and relationships may not be provided, and throughout the disclosure, the same or similar configuration or arrangement elements may be designated by the same reference numerals. Also, because the size and thickness of each configuration or arrangement as illustrated in the drawing may be arbitrarily shown for better understanding and ease of description, embodiments of the present disclosure are not necessarily limited thereto.

In the drawings, the thickness of layers, films, panels, regions, and/or the like may be enlarged for clarity. In the drawings, the thickness of a part of layers, regions, and/or the like may be exaggerated for convenience of description.

It will be understood that if (e.g., when) an element, such as a layer, a film, a region, or a substrate, is referred to as being “on” another element, it may be directly on the other element or intervening elements may also be present therebetween. In contrast, if (e.g., when) an element is referred to as being “directly on” another element, there are no intervening elements present therebetween.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

As used herein, “combination thereof” may refer to a mixture, a stack, a composite, a copolymer, an alloy, a blend, a reaction product, and/or the like of constituents.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within +30%, +20%, +10%, or +5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

As used herein, “substituted” refers to replacement of a hydrogen atom by deuterium, a halogen, a hydroxy group, an amino group, a substituted or unsubstituted C1 to C30 amine group, a nitro group, a substituted or unsubstituted C1 to C40 silyl group, a substituted or unsubstituted C1 to C30 alkyl group, a substituted or unsubstituted C1 to C10 haloalkyl group, a substituted or unsubstituted C1 to C10 alkylsilyl group, a substituted or unsubstituted C3 to C30 cycloalkyl group, a substituted or unsubstituted C6 to C30 aryl group, a substituted or unsubstituted C1 to C20 alkoxy group, or a cyano group. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond (e.g., a carbon-carbon double bond) or triple bond (e.g., a carbon-carbon triple bond).

The alkyl group may be a C1 to C20 alkyl group. For example, the alkyl group may be a C1 to C10 alkyl group or a C1 to C6 alkyl group. For example, a C1 to C4 alkyl group refers to that the alkyl chain contains 1 to 4 carbon atoms and is selected from among methyl, ethyl, propyl, iso-propyl, n-butyl, iso-butyl, sec-butyl, and t-butyl.

The alkyl group refers to a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, and/or the like.

In this description, unless otherwise defined, “cycloalkyl group” refers to a monovalent cyclic aliphatic hydrocarbon group.

As used herein, unless otherwise defined, “alkenyl group” refers to an aliphatic unsaturated alkenyl group including at least one double bond (e.g., a carbon-carbon double bond) as a linear or branched aliphatic hydrocarbon group.

As used herein, unless otherwise defined, “alkynyl group” refers to an aliphatic unsaturated alkynyl group including at least one triple bond (e.g., a carbon-carbon triple bond) as a linear or branched aliphatic hydrocarbon group.

As used herein, “aryl group” refers to a substituent in which all atoms of the cyclic substituent have p-orbitals and these p-orbitals form conjugation, and includes monocyclic or fused ring polycyclic (e.g., rings that share adjacent pairs of carbon atoms) functional groups.

Hereinafter, a method of forming or providing patterns according to one or more embodiments is described in more detail with reference to the accompanying drawings as examples.

A method of forming or providing patterns according to one or more embodiments may include forming or providing an etching target film on a substrate; coating a semiconductor photoresist composition including an organometallic compound and a solvent on the etching target film to form or provide a photoresist film; exposing the photoresist film utilizing a patterned mask; dry developing the photoresist film utilizing gas to form or provide a photoresist pattern; and etching the etching target film utilizing the photoresist pattern as an etching mask.

As the pattern becomes finer, if (e.g., when) the unexposed region is developed utilizing a wet developing process that is generally available, if (e.g., when) the high photoresist selectivity is not satisfied, the pattern may not withstand the surface tension of the developer, and the pattern may collapse, making it difficult to form or provide the desired pattern.

However, in the method of forming or providing patterns according to the present disclosure, by applying a dry process utilizing gas instead of a wet process that is generally available, phenomena of wiggling or pattern collapse due to pattern miniaturization may be prevented (or a degree or occurrence of phenomena of wiggling or pattern collapse due to pattern miniaturization may be reduced).

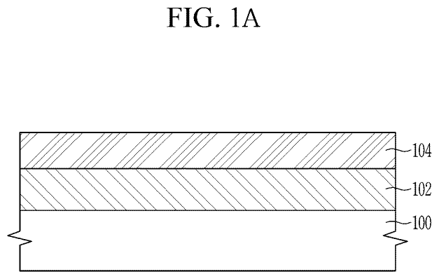

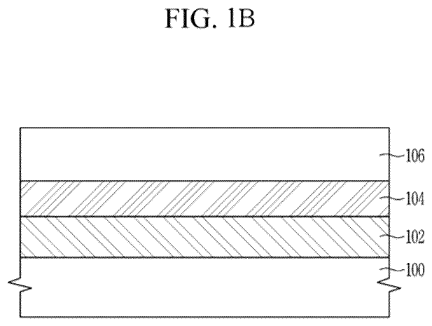

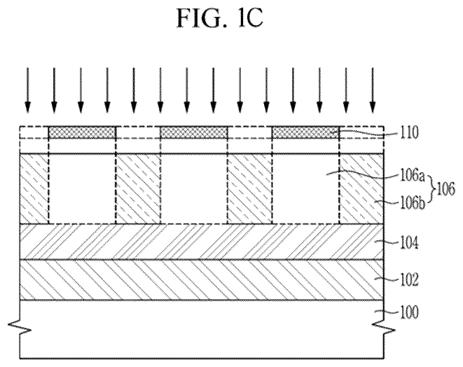

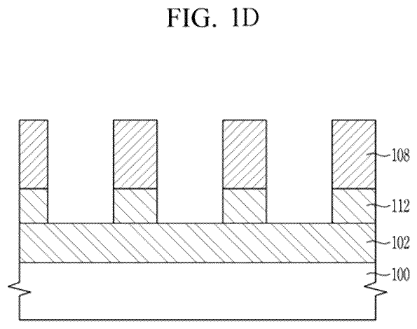

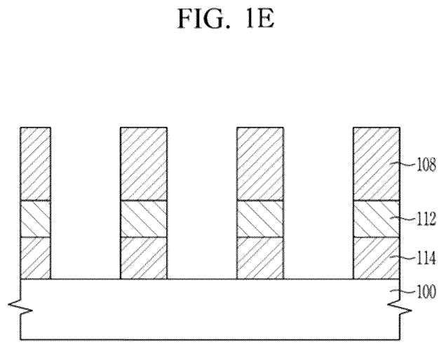

For example, a method of forming or providing patterns according to the present disclosure is described herein in more detail with reference to FIGS. 1A-1E.

Referring to FIG. 1A, an object to etch may be prepared. The object to etch may be a thin film 102 formed or provided on a semiconductor substrate 100. Hereinafter, the object to etch may be limited to the thin film 102. A surface of the thin film 102 may be washed to remove impurities and/or the like remaining thereon. The thin film 102 may be, for example, a silicon nitride layer, a polysilicon layer, or a silicon oxide layer.

Subsequently, the resist underlayer composition to provide a resist underlayer 104 may be spin-coated on the surface of the washed thin film 102. However, embodiments of the present disclosure are not limited thereto, and one or more suitable coating methods that are generally available, for example, a spray coating, a dip coating, a knife edge coating, a printing method, for example, an inkjet printing and a screen printing, and/or the like may be used.

The coating process of the resist underlayer may not be provided, and hereinafter, a process including a coating of the resist underlayer is described in more detail.

Then, the coated composition may be dried and baked to form or provide a resist underlayer 104 on the thin film 102. The baking may be performed at about 100° C. to about 500° C., for example, about 100° C. to about 300° C.

The resist underlayer 104 may be formed or provided between the substrate 100 and a photoresist film 106 and thus may prevent non-uniformity and pattern formability of a photoresist line width (or reduce a degree or occurrence of non-uniformity and pattern formability of a photoresist line width) if (e.g., when) a ray reflected from on the interface between the substrate 100 and the photoresist film 106 or a hardmask between layers is scattered into an unintended photoresist region.

Referring to FIG. 1B, a semiconductor photoresist composition may be spin-coated on an etching target film including the resist underlayer 104 to form or provide a photoresist film 106. The photoresist film 106 may be in the form of a semiconductor photoresist composition coated on a thin film 102 formed or provided on a substrate 100 and then cured through a heat treatment process.

For example, the forming or providing of the pattern utilizing a semiconductor photoresist composition may include a process to coat the semiconductor photoresist composition as described in one or more embodiments by spin coating onto a substrate 100 on which a thin film 102 is formed or provided and a process to dry the coated semiconductor photoresist composition to form or provide a photoresist film 106.

For example, the semiconductor photoresist composition may include an organometallic compound represented by Chemical Formula 1 and a solvent.

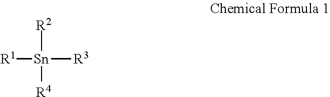

In Chemical Formula 1,
R¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), or a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof), and
at least one selected from among R² to R⁴ may be selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof).

For example, R¹ may be selected from among a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C12 aryl group, and a substituted or unsubstituted C7 to C20 arylalkyl group.

For example, R¹ may be a methyl group, an ethyl group, a propyl group, a butyl group, an isopropyl group, a tert-butyl group, a 1,1-dimethylpropyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof.

For example, at least one selected from among R² to R⁴ may be selected from among an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof).

As another example, the semiconductor photoresist composition may include a first organometallic compound, a second organometallic compound, and a solvent.

In the first organometallic compound, at least one selected from among R² to R⁴ of Chemical Formula 1 may be selected from among an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof), and
in the second organometallic compound, at least one selected from among R² to R⁴ of Chemical Formula 1 may be selected from among an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof).

For example, the first organometallic compound may be represented by Chemical Formula 1A, and the second organometallic compound may be represented by Chemical Formula 1B.

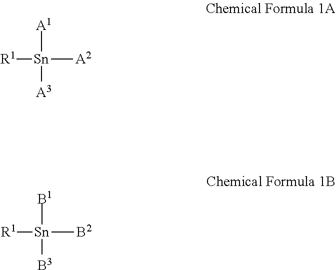

In Chemical Formula 1A and Chemical Formula 1B,
R¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
A¹ to A³ may each independently be selected from among an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof), and
B¹ to B³ may each independently be selected from among an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof).

By mixing two or more types or kinds of organometallic compounds with different ligands, the bridge margin may be improved or enhanced by suppressing curing of the unexposed region (or by reducing a degree or occurrence of curing of the unexposed region), and excellent or suitable coating properties and LER may be implemented by reducing the crystallinity (e.g., a degree or occurrence of the crystallinity) through the introduction of one or more suitable ligands.

The first organometallic compound and the second organometallic compound may be in a weight ratio of about 1:99 to about 99:1.

In one or more embodiments, R¹ may be selected from among a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C12 aryl group, and a substituted or unsubstituted C7 to C20 arylalkyl group, and

R^{d}, R^{e}, R^{f}, R^{g}, R^{h}, Rⁱ, R^{j}, R^{k}, and R^{l} may each independently be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

In one or more embodiments, R¹ may be a methyl group, an ethyl group, a propyl group, a butyl group, an isopropyl group, a tert-butyl group, a 1,1-dimethylpropyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof, and

R^{d}, R^{e}, R^{f}, R^{g}, R^{h}, Rⁱ, R^{j}, R^{k}, and R^{l} may each independently be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

For example, the first organometallic compound may be at least one selected from among the compounds listed in Group 1.

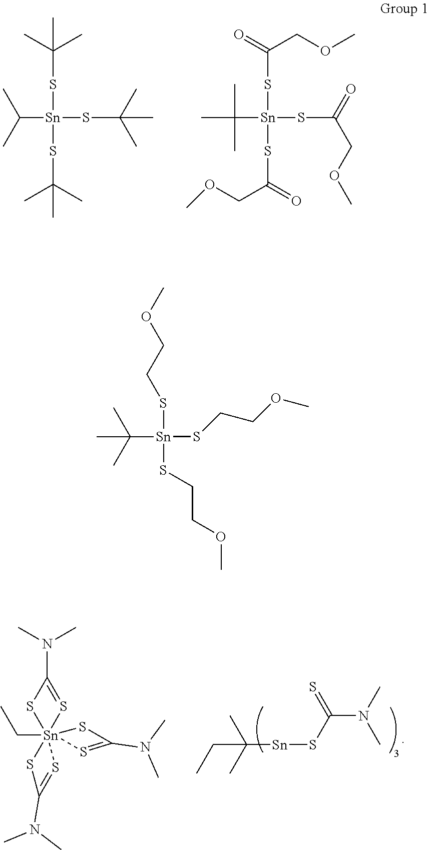

The second organometallic compound may be at least one selected from among the compounds listed in Group 2.

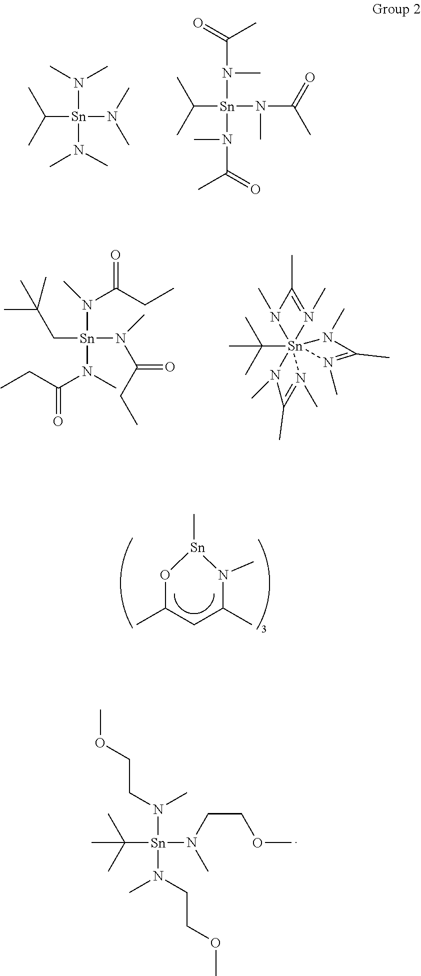

The semiconductor photoresist composition may further include at least one selected from among a surfactant, a dispersant, a moisture absorbent, and a coupling agent.

The surfactant may serve to improve or enhance coating uniformity and improve or enhance wetting of the photoresist composition. For example, the surfactant may be a sulfuric acid ester salt, a sulfonic acid salt, a phosphoric acid ester, a soap, an amine salt, a quaternary ammonium salt, a polyethylene glycol, an alkylphenol ethylene oxide adduct, a polyhydric alcohol, a nitrogen-containing vinyl polymer, or a combination thereof, but embodiments of the present disclosure are not limited thereto. For example, the surfactant may include an alkylbenzenesulfonate salt, an alkylpyridinium salt, polyethylene glycol, and/or a quaternary ammonium salt. If (e.g., when) the photoresist composition includes the surfactant, the surfactant may be in an amount of about 0.001 wt % to about 3 wt % based on a total weight (based on 100 wt %) of the photoresist composition.

The dispersant may serve to uniformly (e.g., substantially uniformly) disperse each component constituting the photoresist composition in the photoresist composition. For example, the dispersant may be an epoxy resin, polyvinyl alcohol, polyvinyl butyral, polyvinylpyrrolidone, glucose, sodium dodecyl sulfate, sodium citrate, oleic acid, linoleic acid, or a combination thereof, but embodiments of the present disclosure are not limited thereto. If (e.g., when) the photoresist composition includes the dispersant, the dispersant may be in an amount of about 0.001 wt % to about 5 wt % based on the total weight (based on 100 wt %) of the photoresist composition.

The moisture absorbent may serve to prevent adverse effects (or to reduce a degree or occurrence of adverse effects) by moisture in the photoresist composition. For example, the moisture absorbent may serve to prevent the metal in the photoresist composition from being oxidized by moisture (or to reduce a degree to or occurrence of which the metal in the photoresist composition is oxidized by moisture). For example, the moisture absorbent may be polyoxyethylene nonylphenolether, polyethylene glycol, polypropylene glycol, polyacrylamide, or a combination thereof, but embodiments of the present disclosure are not limited thereto. If (e.g., when) the photoresist composition includes the moisture absorbent, the moisture absorbent may be in an amount of about 0.001 wt % to about 10 wt % based on the total weight (based on 100 wt %) of the photoresist composition.

The coupling agent may serve to improve or enhance adhesion to the lower film if (e.g., when) the photoresist composition is coated on the lower film. For example, the coupling agent may include a silane coupling agent. The silane coupling agent may be vinyltrimethoxysilane, vinyltriethoxysilane, vinyl trichlorosilane, vinyltris(β-methoxyethoxy) silane, 3-methacryloxypropyltrimethoxysilane, 3-acryloxypropyl trimethoxysilane, p-styryl trimethoxysilane, 3-methacryloxypropylmethyldimethoxysilane, 3-methacryloxypropylmethyldiethoxysilane, or trimethoxy [3-(phenylamino)propyl]silane, but embodiments of the present disclosure are not limited thereto. If (e.g., when) the photoresist composition includes the coupling agent, the coupling agent may be in an amount of about 0.001 wt % to about 5 wt % based on the total weight (based on 100 wt %) of the photoresist composition.

Next, a first baking process may be performed to heat the substrate 100 on which the photoresist film 106 is formed or provided. The first baking process may be performed at a temperature of about 80° C. to about 120° C.

Referring to FIG. 1C, the photoresist film 106 may be selectively exposed utilizing a patterned mask 110.

Examples of light that may be used in the exposure process may include light having a high energy wavelength of about 3 nm to about 15 nm, for example, extreme ultraviolet (EUV; wavelength of 13.5 nm) and/or other sources, such as electron beam (e-beam).

The exposed region 106b of the photoresist film 106 may have a different solubility from the unexposed region 106a of the photoresist film 106 by forming or providing a polymer by a crosslinking reaction, such as condensation between organometallic compounds.

Subsequently, the substrate 100 may be subjected to a second baking process. The second baking process may be performed at a temperature of about 90° C. to about 200° C. The exposed region 106b of the photoresist film 106 may become easily indissoluble regarding a developer due to the second baking process.

Next, the forming or providing of the photoresist pattern may be performed by developing the photoresist film.

In FIG. 1D, the photoresist pattern 108 formed or provided by removing a photoresist film 106 corresponding to the unexposed region by development is illustrated. For example, a photoresist pattern 108 corresponding to the negative tone image may be completed by removing the photoresist film 106a corresponding to the unexposed region through dry development utilizing gas.

This dry developing method may be performed utilizing a mild plasma (e.g., high pressure, low power) or thermal process while flowing a dry developing chemical, such as boron trichloride (BCl₃) and/or another Lewis acid. In one or more embodiments, BCl₃ may rapidly remove the photoresist film 106a corresponding to the unexposed region, leaving the exposed region 106b that may be transferred to underlying layers by plasma-based etching processes, such as etching processes that are generally available.

The plasma processes may include Transformer Coupled Plasma (TCP), Inductively Coupled Plasma (ICP) and/or Capacitively Coupled Plasma (CCP) and may employ equipment and techniques that are generally available in the art. For example, the process may be performed at pressures greater than about 5 mT (e.g., greater than about 15 mT) and power levels less than about 1000 W (e.g., less than about 500 W). The temperature may be in a range of 0° C. to about 300° C. (e.g., about 30° C. to about 120° C.) at a flow rate in a range of about 100 sccm to about 1000 sccm (standard cubic centimeters per minute), for example, about 500 sccm, for about 1 second to about 3000 seconds (e.g., about 10 seconds to about 600 seconds).

In thermal development processes, the substrate may be exposed to dry developing chemicals (e.g., Lewis acids) in a vacuum chamber (e.g., an oven). Suitable chambers may include vacuum lines, dry developing chemical gas (e.g., BCl₃) lines, and heaters for temperature control. In one or more embodiments, the interior of the chamber may be coated with corrosion resistant films, such as organic polymers and/or inorganic coatings. One example of the coating may be polytetrafluoroethylene (PTFE; e.g., Teflon™). These materials may be utilized in the thermal processes as described in one or more embodiments without the risk of removal by plasma exposure.

In one or more embodiments, the methods as described in one or more embodiments may combine all dry methods of film formation by vapor deposition, extreme ultraviolet (EUV) lithographic photopatterning, and dry development. In these processes, the substrate may be moved directly into a dry developing/etching chamber following photopatterning in an EUV scanner. The dry development as described in one or more embodiments may provide one or more advantages or benefits over wet development that is generally available in the art. For example, it may prevent line collapse (or reduce a degree or occurrence of line collapse) due to surface tension in wet development, eliminate the use of organic solvent developers, and be more advantageous or beneficial if (e.g., when) implemented with a smaller pitch.

As described in one or more embodiments, the line and space widths in the 1:1 line/space pattern of the photoresist pattern 108 formed or provided after exposure and dry development by light having a high energy wavelength, such as extreme ultraviolet (EUV; wavelength of 13.5 nm), and/or other sources electron beam (e-beam) may each independently be in a range of about 5 nm to about 100 nm. For example, the line and space line widths may be in a range of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

Subsequently, the photoresist pattern 108 may be utilized as an etching mask to etch the resist underlayer 104. Through this etching process, an organic film pattern 112 may be formed or provided. The organic film pattern 112 may also have a width corresponding to a width of the photoresist pattern 108.

Referring to FIG. 1E, the exposed thin film 102 may be etched by applying the photoresist pattern 108 as an etching mask. As a result, the thin film may be formed or provided as a thin film pattern 114.

In the exposure process, the thin film pattern 114 formed by utilizing the photoresist pattern 108 that is formed or provided through the exposure process performed by utilizing an EUV light source may have a width corresponding to a width of the photoresist pattern 108. For example, the thin film pattern 114 may have a width of about 5 nm to about 100 nm which is substantially equal to a width of the photoresist pattern 108. For example, the thin film pattern 114 formed or provided by utilizing the photoresist pattern 108 formed or provided through the exposure process performed by utilizing an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width of less than or equal to about 20 nm, like a width of the photoresist pattern 108.

Hereinafter, one or more embodiments of the present disclosure will be described in more detail through examples of the method of forming or providing patterns. However, embodiments of the present disclosure are not restricted by the following examples.

### EXAMPLES

### Synthesis of Organometallic Compounds

### Synthesis Example 1

In a 100 mL round-bottomed flask, 5.2 g (102.03 mmol) of LiNMe₂ was dissolved in anhydrous hexane and then, cooled to −78° C. Subsequently, 9.2 g (34.01 mmol) of isopropyltin trichloride was slowly added thereto in a dropwise fashion and then, reacted at room temperature for 24 hours. When the reaction was completed, the resultant was filtered, concentrated, and vacuum-dried, obtaining the organometallic compound represented by Chemical Formula 6.

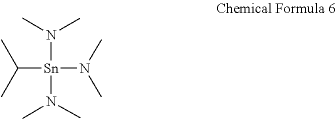

### Synthesis Example 2

In a 1 L round-bottomed flask, iPrSn(NEt₂)₃ (18.9 g, 50 mmol) was dissolved in 500 mL of anhydrous hexane and then, cooled to −78° C. Subsequently, N-methylacetamide (11 g, 150 mmol) was slowly added thereto in a dropwise fashion and then, reacted at room temperature for 24 hours. When the reaction was completed, the resultant was filtered, concentrated, and vacuum-dried, obtaining the organometallic compound represented by Chemical Formula 7.

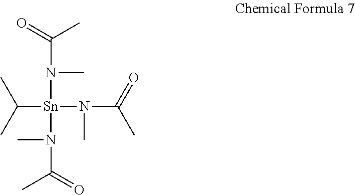 [SMILES: CC(=O)[N](C)[Sn]([CH](C)C)([N](C)C(C)=O)[N](C)C(C)=O]

### Synthesis Example 3

In a 1 L round-bottomed flask, iPrSn(NEt₂)₃ (18.9 g, 50 mmol) was dissolved in 500 mL of anhydrous hexane and then, cooled to −78° C. Subsequently, 2-methyl-2-propanethiol (13.53 g, 150 mmol) was slowly added thereto in a dropwise fashion and then, reacted at room temperature for 24 hours. When the reaction was completed, the resultant was filtered, concentrated, and vacuum-dried, obtaining the organometallic compound represented by Chemical Formula 8.

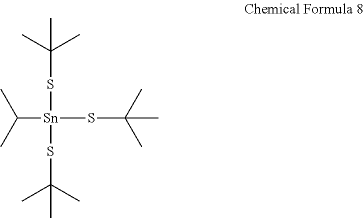 [SMILES: C[CH](C)[Sn]([S]C(C)(C)C)([S]C(C)(C)C)[S]C(C)(C)C]

### Synthesis Example 4

10 g of an organotin compound represented by Chemical Formula A was dissolved in 30 mL of toluene, and 8 g of 2-methoxyethanethioic S-acid was slowly added thereto and then, stirred at room temperature (20±5° C.) for 6 hours. Subsequently, the toluene and the separated propionic acid were removed by vacuum distillation, obtaining the organometallic compound represented by Chemical Formula 9.

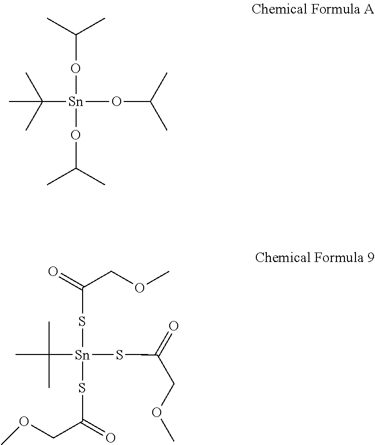

### Synthesis Example 5

In a 250 mL two-neck round-bottom flask, 20 g (51.9 mmol) of Ph₃SnCl was dissolved in 70 mL of THF and then, cooled to 0° C. in an ice bath. Subsequently, a 1 M THF solution (62.3 mmol) of tert-butyl magnesium chloride (tBuMgCl) was slowly added thereto in a dropwise fashion. When the addition was completed, the mixture was stirred at room temperature (25±3° C.) for 12 hours, obtaining the t-BuSnPh₃ compound.

Subsequently, the t-BuSnPhs compound (10 g, 24.6 mmol) was dissolved in 50 mL of CH₂Cl₂, and 3 equivalents (73.7 mmol) of a 2 M HCl diethyl ether solution was slowly added thereto in a dropwise fashion at −78° C. for 30 minutes. After stirring the obtained mixture at room temperature for 12 hours, the solvent was concentrated and vacuum-distilled, obtaining the t-BuSnCl₃ compound.

Subsequently, 32 mL of propionic acid was slowly added in a dropwise fashion to 10 g (25.6 mmol) of the t-BuSnCl₃ compound at room temperature and then, heated under reflux for 12 hours. After increasing the temperature to room temperature, the propionic acid was vacuum-distilled, obtaining the compound represented by Chemical Formula 10.

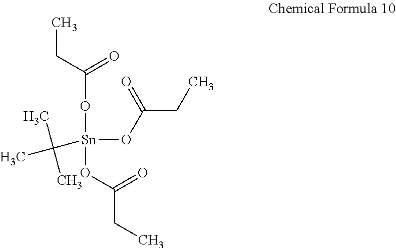 [SMILES: CCC(=O)[O][Sn]([O]C(=O)CC)([O]C(=O)CC)[C](C)(C)C]

### Preparation Examples 1 to 9: Preparation of Semiconductor Photoresist Compositions

Each semiconductor photoresist composition respectively including the organometallic compounds represented by Synthesis Examples 1 to 5 was prepared as shown in Table 1.

The semiconductor photoresist composition was prepared by respectively dissolving the compounds at 3 wt % in 4-methyl-2-pentanol and then, filtered with a 0.1 μm PTFE syringe filter, and as a substrate for depositing a thin film, a circular silicon wafer having a diameter of 4 inches and a native-oxide surface was used. Before depositing a resist thin film, the wafer was treated in a UV ozone cleaning system for 10 minutes, and the resist composition was spin-coated on the wafer at 1500 rpm for 30 seconds and then, baked at 100° C. for 120 seconds to form or provide the thin film. As a result of measuring a thickness of the film after coating and baking through ellipsometry, the thickness was about 25 nm.

TABLE 1

| | First | Second | |
|---|---|---|---|
| | organometallic | organometallic | Organometallic |
| | compound | compound | compound |
| | (wt %) | (wt %) | (wt %) |
| Preparation | — | Chemical | — |
| Example 1 | | Formula 6 | |
| | | (3) | |
| Preparation | Chemical | — | — |
| Example 2 | Formula 8 | | |
| | (3) | | |
| Preparation | Chemical | Chemical | — |
| Example 3 | Formula 8 | Formula 6 | |
| | (1.5) | (1.5) | |
| Preparation | Chemical | Chemical | — |
| Example 4 | Formula 8 | Formula 7 | |
| | (1.5) | (1.5) | |
| Preparation | Chemical | Chemical | — |
| Example 5 | Formula 9 | Formula 6 | |
| | (1.5) | (1.5) | |
| Preparation | Chemical | Chemical | — |
| Example 6 | Formula 9 | Formula 7 | |
| | (1.5) | (1.5) | |
| Preparation | Chemical | Chemical | — |
| Example 7 | Formula 8 | Formula 6 | |
| | (2.4) | (0.6) | |
| Preparation | Chemical | Chemical | — |
| Example 8 | Formula 8 | Formula 6 | |
| | (0.6) | (2.4) | |
| Preparation | — | — | Chemical |
| Example 9 | | | Formula 10 |
| | | | (3) |

### Formation of Patterns

### Examples 1 to 8 and Comparative Example 1 (Dry Development)

After spin-coating hexamethyldisilazane (HMDS) on the surface of an 8-inch silicon wafer to make the surface hydrophobic, each of the metal-containing photoresist (PR) compositions according to Preparation Examples 1 to 9 was spin-coated at 1,500 rpm for 30 seconds thereon and then, heat-treated at 160° C. for 60 seconds.

Onto the coated wafer, a lattice array of 200 μm*30 μm rectangular pads was projected by using EUV light (Lawrence Berkeley National Laboratory Micro Exposure Tool, MET5). The pad exposure time was adjusted so that the EUV light in an increasing dose was applied to each pad.

Subsequently, the resist and the substrate were exposed at 160° C. on a hot plate for 90 seconds and then, baked (post-exposure baked, PEB).

The baked film was exposed to hydrogen bromide vapor by utilizing dry developing equipment. The hydrogen bromide was controlled at a vapor flow rate of 5 sccm to 500 sccm (standard cubic centimeters per minute) to provide a chamber pressure of 0.1 torr or 5 torr. The wafer sample was heated at 120° C. to 200° C. The heated wafer sample was exposed to the flowing hydrogen bromide for one or more times ranging from 0 second to 600 seconds. After removing the unexposed coating portion therefrom to form or provide a negative tone image, the process was completed.

### Comparative Examples 2 to 3 (Wet Development)

The metal-containing photoresist (PR) compositions according to Preparation Examples 3 and 9 were respectively immersed in a developer (2-heptanone) for 30 seconds rather than dry-developed by utilizing a dry developer after the coating and the exposing and then, additionally washed with the same developer for 10 seconds to remove the unexposed coating portion, forming or providing a negative tone image. Finally, a heat treatment at 150° C. for 1 minute was performed, completing the process.

### Evaluation: Analysis of Pattern Bridge Characteristics

The resist patterns according to Examples 1 to 8 and Comparative Examples to 3 were respectively measured with respect to an average line width for each field along the scanned dose range by using critical dimension scanning electron microscope (CD-SEM; CG4100, Hitachi, Ltd.) to check presence or absence of bridge defects according to the pattern line width, and the results are shown in Table 2.

When there were no bridge defects, “X” was given, but when there were the bridge defects, “∘” was given.

TABLE 2

| | | | Bridge defects | | |
|---|---|---|---|---|---|
| | | | Pattern | Pattern | Pattern |
| | | | line | line | line |
| | Photoresist | Development | width | width | width |
| | composition | method | (26 nm) | (24 nm) | (18 nm) |
| Example 1 | Preparation | dry | X | X | X |
| | Example 1 | development | | | |
| Example 2 | Preparation | dry | X | X | X |
| | Example 2 | development | | | |
| Example 3 | Preparation | dry | X | X | X |
| | Example 3 | development | | | |
| Example 4 | Preparation | dry | X | X | X |
| | Example 4 | development | | | |
| Example 5 | Preparation | dry | X | X | X |
| | Example 5 | development | | | |
| Example 6 | Preparation | dry | X | X | X |
| | Example 6 | development | | | |
| Example 7 | Preparation | dry | X | X | X |
| | Example 7 | development | | | |
| Example 8 | Preparation | dry | X | X | X |
| | Example 8 | development | | | |
| Comparative | Preparation | dry | ◯ | ◯ | ◯ |
| Example 1 | Example 9 | development | | | |
| Comparative | Preparation | wet | ◯ | ◯ | ◯ |
| Example 2 | Example 3 | development | | | |
| Comparative | Preparation | wet | X | ◯ | ◯ |
| Example 3 | Example 9 | development | | | |

Referring to Table 2, the methods of forming or providing patterns according to Examples 1 to 8, compared with those of Comparative Examples 1 to 3, were confirmed to provide patterns with excellent or suitable resolution but without bridge defects.

Hereinbefore, certain embodiments of the present disclosure have been described and illustrated, however, it should be apparent to a person having ordinary skill in the art that the present disclosure is not limited to the embodiments as described and may be suitably modified and transformed without departing from the spirit and scope of the present disclosure. Accordingly, the modified or transformed embodiments as such may not be understood separately from the technical ideas and aspects of one or more embodiments of the present disclosure, and the modified embodiments may be within the scope of the appended claims and equivalents thereof of the present disclosure.

Reference Numerals

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A method of forming patterns, comprising:
forming an etching target film on a substrate;
coating a semiconductor photoresist composition comprising an organometallic compound and a solvent on the etching target film to form a photoresist film;
exposing the photoresist film utilizing a patterned mask;
dry developing the photoresist film utilizing gas to form a photoresist pattern; and
etching the etching target film utilizing the photoresist pattern as an etching mask.

2. The method of forming patterns as claimed in claim 1, wherein:
the organometallic compound is represented by Chemical Formula 1: 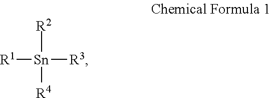
wherein, in Chemical Formula 1,
R¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), or a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof), and
at least one selected from among R² to R⁴ is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof).

3. The method of forming patterns as claimed in claim 2, wherein:
at least one selected from among R² to R⁴ is selected from among an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof).

4. The method of forming patterns as claimed in claim 3, wherein:
the organometallic compound comprises:
a first organometallic compound wherein at least one selected from among R² to R⁴ is selected from among an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, a substituted or unsubstituted C1 to C20 amine group, or a combination thereof); and
a second organometallic compound wherein at least one selected from among R² to R⁴ is selected from among an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof).

5. The method of forming patterns as claimed in claim 4, wherein:
the first organometallic compound is represented by Chemical Formula 1A, and
the second organometallic compound is represented by Chemical Formula 1B: 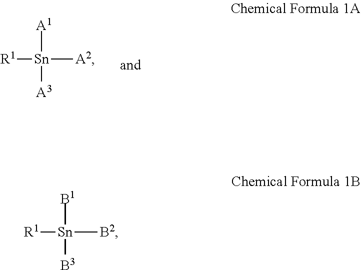
wherein, in Chemical Formula 1A and Chemical Formula 1B,
R¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
A¹ to A³ are each independently selected from among an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and a dithiocarboxyl group (—S(CS)R^{m}, wherein R^{m} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and
B¹ to B³ are each independently selected from among an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof), and an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C1 to C20 alkoxy group, a substituted or unsubstituted C6 to C30 aryl group, or a combination thereof).

6. The method of forming patterns as claimed in claim 5, wherein:
R¹ is selected from among a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C12 aryl group, and a substituted or unsubstituted C7 to C20 arylalkyl group, and
R^{d}, R^{e}, R^{f}, R^{g}, R^{h}, Rⁱ, R^{j}, R^{k}, and R^{l} are each independently a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or combination thereof.

7. The method of forming patterns as claimed in claim 5, wherein:
R¹ is a methyl group, an ethyl group, a propyl group, a butyl group, an isopropyl group, a tert-butyl group, a 1,1-dimethylpropyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof, and
R^{d}, R^{e}, R^{f}, R^{g}, R^{h}, Rⁱ, R^{j}, R^{k}, and R^{l} are each independently an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

8. The method of forming patterns as claimed in claim 5, wherein:
the first organometallic compound is at least one compound selected from among the compounds listed in Group 1:

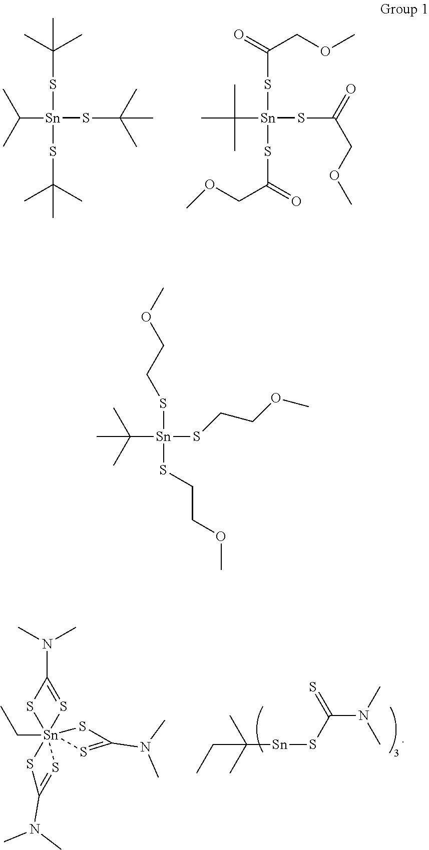

9. The method of forming patterns as claimed in claim 5, wherein:
the second organometallic compound is at least one selected from among the compounds listed in Group 2:

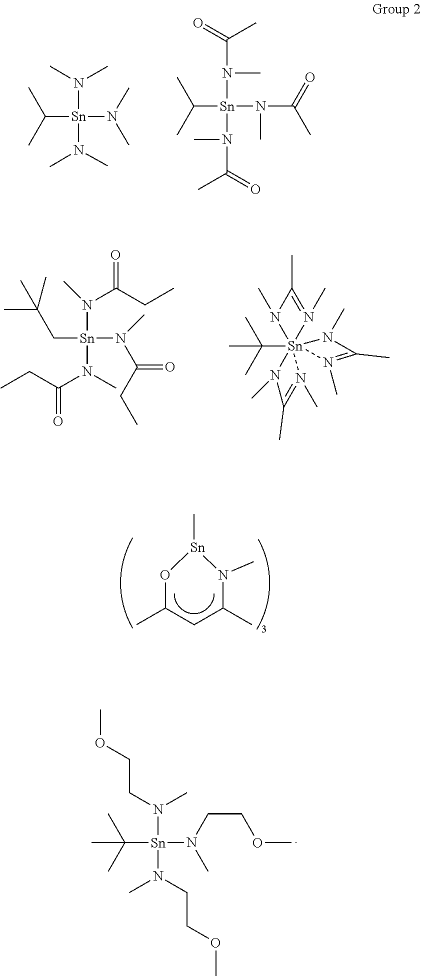

10. The method of forming patterns as claimed in claim 1, wherein:
the exposing of the photoresist film is performed using light having a high energy wavelength of 3 nm to 15 nm.

11. The method of forming patterns as claimed in claim 1, wherein:
a line and space widths in the 1:1 line/space pattern of the photoresist pattern after developing are each independently in a range of 5 nm to 100 nm.

12. The method of forming patterns as claimed in claim 4, wherein:
a weight ratio of the first organometallic compound to the second organometallic compound is 1:99 to 99:1.

13. The method of forming patterns as claimed in claim 1, wherein:
the semiconductor photoresist composition further comprises at least one selected from among a surfactant, a dispersant, a moisture absorbent, a coupling agent, and a combination thereof.

14. The method of forming patterns as claimed in claim 13, wherein:
the surfactant comprises at least one selected from among a sulfuric acid ester salt, a sulfonic acid salt, a phosphoric acid ester, a soap, an amine salt, a quaternary ammonium salt, a polyethylene glycol, an alkylphenol ethylene oxide adduct, a polyhydric alcohol, a nitrogen-containing vinyl polymer, and a combination thereof.

15. The method of forming patterns as claimed in claim 13, wherein:
the surfactant is in an amount of 0.001 wt % to 3 wt % based on 100 wt % of the semiconductor photoresist composition.

16. The method of forming patterns as claimed in claim 13, wherein:
the dispersant comprises at least one selected from among an epoxy resin, polyvinyl alcohol, polyvinyl butyral, polyvinylpyrrolidone, glucose, sodium dodecyl sulfate, sodium citrate, oleic acid, linoleic acid, and a combination thereof.

17. The method of forming patterns as claimed in claim 13, wherein:
the dispersant is in an amount of 0.001 wt % to 5 wt % based on 100 wt % of the semiconductor photoresist composition.

18. The method of forming patterns as claimed in claim 13, wherein:
the moisture absorbent comprises at least one selected from among polyoxyethylene nonylphenolether, polyethylene glycol, polypropylene glycol, polyacrylamide, and a combination thereof.

19. The method of forming patterns as claimed in claim 13, wherein:
the moisture absorbent is in an amount of 0.001 wt % to 10 wt % based on 100 wt % of the semiconductor photoresist composition.

20. The method of forming patterns as claimed in claim 13, wherein:
the coupling agent is in an amount of 0.001 wt % to 5 wt % based on 100 wt % of the semiconductor photoresist composition.
